(19) United States
(12) Patent Application Publication
(10) Pub. No.: US 2024/0405718 A1
(43) Pub. Date: Dec. 5, 2024

(54) OSCILLATOR CIRCUIT

(71) Applicant: Nuvoton Technology Corporation Japan, Kyoto (JP)

(72) Inventor: Seiji YAMAHIRA, Kyoto (JP)

(21) Appl. No.: 18/807,317

(22) Filed: Aug. 16, 2024

Related U.S. Application Data
(63) Continuation of application No. PCT/JP2023/004670, filed on Feb. 10, 2023.

(30) Foreign Application Priority Data
Feb. 24, 2022 (JP) 2022-027275

(51) Int. Cl. H03B 5/04; H03B 5/06; H03B 5/36

(52) U.S. Cl. CPC H03B 5/04; H03B 5/06; H03B 5/36

(57) ABSTRACT

An oscillator circuit includes an oscillator and an amplifier that amplifies a voltage of the oscillator. The amplifier includes an amplifier circuit that includes: an amplifier device (an inverter) that inverts and amplifies an input voltage and outputs a resulting voltage; a first element (a capacitor) connected to an input node of the amplifier device; and a second element (a capacitor) identical to the first element in type and connected between the input node and an output node of the amplifier device.

### CROSS REFERENCE TO RELATED APPLICATIONS

This is a continuation application of PCT International Application No. PCT/JP2023/004670 filed on Feb. 10, 2023, designating the United States of America, which is based on and claims priority of Japanese Patent Application No. 2022-027275 filed on Feb. 24, 2022. The entire disclosures of the above-identified applications, including the specifications, drawings and claims are incorporated herein by reference in their entirety.

### FIELD

The present disclosure relates to an oscillator circuit.

### BACKGROUND

Oscillator circuits including an oscillator such as a crystal reach a steady oscillation state by repeatedly inverting and amplifying, by an amplifier that includes an inverter etc., a minute voltage generated by the oscillator at the time of startup and feeding back the amplified voltage to the oscillator. The oscillator circuit is required to operate stably not only in the steady oscillation state but also during the period from the startup to the steady oscillation state, and a short startup time of the oscillator circuit is also desired. A short startup time is further desired from the viewpoint of current consumption as well since oscillator circuits including an oscillator consume a large amount of current at the time of startup. To shorten the startup time of the oscillator circuit, there is a means for increasing the voltage amplification factor by using an amplifier that includes inverters in a plurality of stages. However, excessive voltage amplification by the amplifier can induce parasitic oscillation and cause abnormal oscillation in the oscillator having a plurality of parasitic oscillations in addition to the main oscillation used in the oscillator circuit. Therefore, although the amplifier having a high voltage amplification factor achieves a short startup time of the oscillator circuit, such an amplifier can be a cause for inducing parasitic oscillation. Conventionally, in order to achieve both a shorter startup time of the oscillator circuit and avoidance of parasitic oscillation by using an amplifier that includes inverters in a plurality of stages, a configuration has been proposed which includes a bandpass filter having a high-pass filter on the input side and a low-pass filter on the output side of each inverter and in which the voltage is amplified only in the frequency band of the main oscillation of the oscillator (Patent Literature (PTL) 1).

### CITATION LIST

### Patent Literature

PTL 1: Japanese Patent No. 5028543

### SUMMARY

### Technical Problem

However, with the configuration described in PTL 1, the frequency band of the bandpass filter of the amplifier is limited to only the frequency band of the main oscillation of the oscillator to inhibit abnormal oscillation caused by parasitic oscillation, and thus it is difficult to use the same oscillator circuit when an oscillator different in main oscillation is used, thereby hindering versatile use of the oscillator circuit.

The present disclosure has been conceived to address the above circumstances, and in order to apply the same oscillator circuit to a greater number of oscillators, the startup time is shortened and countermeasures against abnormal oscillation are taken not by limiting to a narrow frequency band using a bandpass filter, etc. in the amplifier but by setting the voltage amplification factor in a wide frequency band. This is to provide a versatile oscillator circuit which can be used even for an oscillator different in main oscillation.

### Solution to Problem

In order to address the circumstances described above, an oscillator circuit according to the present disclosure includes: an oscillator; and an amplifier that amplifies a voltage of the oscillator, wherein the amplifier includes an amplifier circuit that includes: an amplifier device; a first element connected to an input node of the amplifier device; and a second element identical to the first element in type and connected between the input node and an output node of the amplifier device. This makes it possible to set a voltage amplification factor of the amplifier that includes the amplifier circuit.

### Advantageous Effects

Accordingly, it is possible to set in a wide frequency band the voltage amplification factor of the amplifier circuit included in the amplifier, and the voltage amplification factor of the amplifier can be avoided from being excessive. Abnormal oscillation attributable to parasitic oscillation of the oscillator can be avoided, and the startup time of the oscillator circuit can be shortened. In addition, since the voltage amplification factor is set in a wide frequency band, it is easier to use the same oscillator circuit for an oscillator different in main oscillation, thus making the oscillator circuit versatile. The oscillator circuit for the oscillator consumes the most current during the startup time; however, by shortening the startup time, it is possible to reduce unnecessary current consumption. This feature makes it possible to also reduce the current consumption of IoT devices and mobile devices that transition from the standby state to the recovery state many times.

In variations, it is also possible to meet the specifications of the excitation level of the oscillator by setting the capacitance of a capacitor provided on the input side of the inverter included in each of the amplifier circuits included in the amplifier and the capacitance of a capacitor provided between the input and the output of the inverter, to optimal values according to a control signal.

### BRIEF DESCRIPTION OF DRAWINGS

These and other advantages and features will become apparent from the following description thereof taken in conjunction with the accompanying Drawings, by way of non-limiting examples of an embodiment disclosed herein.

FIG. 1 is a circuit diagram illustrating a configuration of an oscillator circuit according to Embodiment 1 of the present disclosure.

FIG. 2 is an equivalent circuit diagram of amplifier circuits illustrated in FIG. 1.

FIG. 3 is an equivalent circuit diagram including an amplifier circuit and a load capacitor illustrated in FIG. 1.

FIG. 4 is a circuit diagram illustrating another configuration of feedback resistors illustrated in FIG. 1.

FIG. 5 is a circuit diagram illustrating a variation of an amplifier illustrated in FIG. 1.

FIG. 6 is a circuit diagram illustrating another configuration of the amplifier circuits illustrated in FIG. 5.

FIG. 7 is a circuit diagram illustrating another configuration of the amplifier illustrated in FIG. 1.

FIG. 8 is a circuit diagram illustrating a variation of the amplifier circuits illustrated in FIG. 1.

FIG. 9 is an equivalent circuit diagram of the amplifier circuits illustrated in FIG. 8.

### DESCRIPTION OF EMBODIMENT

Hereinafter, an exemplary embodiment of the present disclosure will be described in detail with reference to the drawings. It should be noted, however, that in the embodiment, constituent elements having the same function share the same reference sign, and duplicate descriptions thereof will be omitted.

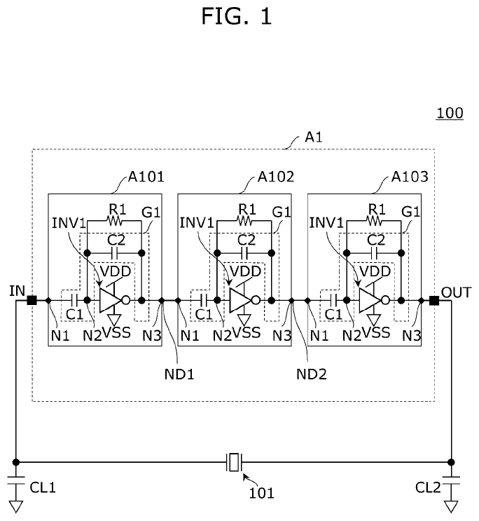

FIG. 1 illustrates Embodiment 1 of the present disclosure and is a circuit diagram illustrating a configuration of oscillator circuit 100. In the diagram, 101 denotes an oscillator made of crystal or ceramic, for example, CL1 and CL2 denote load capacitors connected to the two ends of oscillator 101, and A1 denotes an amplifier that: includes input terminal IN and output terminal OUT; receives at input terminal IN an input of a voltage generated by oscillator 101, as voltage VIN; inverts and amplifies the voltage received; and feeds back from output terminal OUT the resulting voltage to oscillator 101 as voltage VOUT. As illustrated in FIG. 1, oscillator circuit 100 includes oscillator 101 and amplifier A1 that amplifies the voltage of oscillator 101.

Amplifier A1 includes, in a plurality of stages, amplifier circuits A101, A102, and A103 each of which inverts and amplifies an input voltage and outputs the resulting voltage. Amplifier A1 includes node ND1 between amplifier circuits A101 and A102 and node ND2 between amplifier circuits A102 and A103.

Amplifier circuits A101, A102, and A103 have the same configuration, and each of amplifier circuits A101, A102, and A103 includes node N1 as an input node, node N2 as an internal node, and node N3 as an output node. Each of amplifier circuits A101, A102, and A103 includes inverter INV1, gain setter G1, and feedback resistor R1.

Inverter INV1 is an example of the amplifier device that is connected between node N2 and node N3 and inverts and amplifies an input voltage and outputs the resulting voltage.

In each of amplifier circuits A101, A102, and A103, gain setter G1 is a circuit part that sets a voltage amplification factor of the corresponding amplifier circuit, and includes capacitor C1 and capacitor C2. Capacitor C1 is an example of the first element and the first capacitor connected between node N1 and node N2 that is the input node of inverter INV1. Capacitor C2 is an example of the second element and the second capacitor connected between node N2 that is the input node of inverter INV1 and node N3 that is the output node of inverter INV1. As can be seen from above, the second element is identical to the first element in type. Here, the type of an element is a group classified by the properties, form, etc. of the element, and is capacitor, resistor, or inductor, for example. The amplification factor of amplifier A1 is set based on the impedance of the first element and the impedance of the second element. Feedback resistor R1 is a resistor for setting a direct-current bias voltage (hereinafter referred to as a DC bias) of an input voltage of inverter INV1. Here, inverter INV1 is driven between power supply voltage VDD and ground VSS and has mutual conductance gm1.

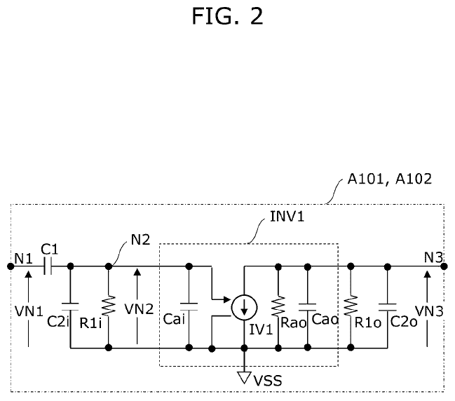

FIG. 2 illustrates an equivalent circuit of amplifier circuit A101. Note that the equivalent circuit of amplifier circuit A102 is the same as the equivalent circuit of amplifier circuit A101. VN1 denotes the voltage at node N1, VN2 denotes the voltage applied to inverter INV1, VN3 denotes the voltage at output node N3, and inverter INV1 can be replaced with voltage-controlled current source IV1, input capacitor Cai, output capacitor Cao, and output resistor Rao. Here, the current value of voltage-controlled current source IV1 is expressed as (gm1·VN2). Furthermore, capacitor C2 can be replaced with capacitor C2i on the input side and capacitor C2o on the output side when capacitor C2 is converted into an equivalent circuit, and feedback resistor R1 can be replaced with resistor R1i on the input side and resistor R1o on the output side when feedback resistor R1 is converted into an equivalent circuit.

Here, when the voltage amplification factor of inverter INV1 is |Av| and voltage amplification factor |Av| is sufficiently greater than 1, capacitors C2i and C2o on the input and output sides of inverter INV1 and resistors R1i and R1o on the input and output sides of inverter INV1, which are obtained by the above conversion, are expressed as below using capacitor C2 and feedback resistor R1. Here, |Av| denotes the magnitude of a vector (hereinafter, “∥” indicates the magnitude of a vector and the minus sign of “∥” indicates that the input/output is logically inverted).

$$Capacitor C 2 i = ( 1 + \vert Av \vert ) \times C 2 = \vert Av \vert \times C 2 \qquad ( 1 )$$

$$Capacitor C 2 o = ( 1 + 1 / \vert Av \vert ) \times C 2 = C 2 \qquad ( 2 )$$

$$Resistor R 1 i = ( 1 / ( 1 + \vert Av \vert ) ) \times R 1 = R 1 / \vert Av \vert \qquad ( 3 )$$

$$Resistor R 1 o = ( 1 / ( 1 + 1 / \vert Av \vert ) ) \times R 1 = R 1 \qquad ( 4 )$$

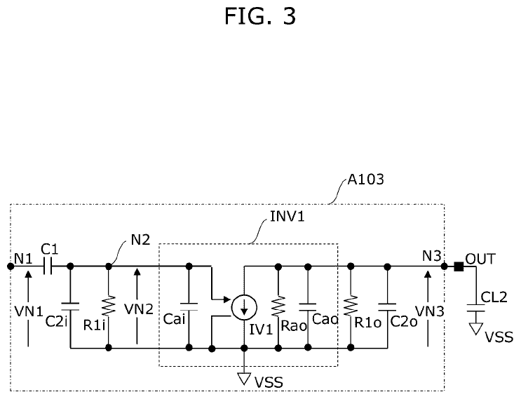

FIG. 3 illustrates an equivalent circuit obtained by adding, to an equivalent circuit of amplifier circuit A103, load capacitor CL2 connected to output terminal OUT. Note that amplifier circuit A103 is the same as amplifier circuits A101 and A102 in configuration and equivalent circuit.

Using the equivalent circuits illustrated in FIG. 2 and FIG. 3, voltage amplification factor |Gx|, which is voltage |VOUT| at output terminal OUT relative to voltage |VIN| at input terminal IN of amplifier A1, is solved. Here, when the voltage amplification factors of amplifier circuits A101, A102, and A103 are |Gx1|, |Gx2|, and |Gx3|, respectively, voltage amplification factor |Gx| of amplifier A1 is expressed as follows:

$$\vert Gx \vert = \vert V OUT \vert / \vert V IN \vert = \vert Gx 1 \vert \times \vert Gx 2 \vert \times \vert Gx 3 \vert \qquad ( 5 )$$

First, voltage amplification factor |Gx1| of amplifier circuit A101 is solved. Voltage amplification factor |Gx1| of amplifier circuit A101 can be expressed as follows using the voltage at each node.

$$\vert Gx 1 \vert = ( \vert V N 3 / V N 1 \vert ) = ( \vert V N 3 / V N 2 \vert \times \vert V N 2 / V N 1 \vert ) \qquad ( 6 )$$

(|VN2/VN1|) in Expression (6) is solved. For node N2 in FIG. 2, solving the nodal equation of Kirchhoff's law with admittance Y1 as Y1=jωC1 and admittance Y2 as Y2=(1+jω(C2i+Cai)×R1i)/R1i gives (VN1−VN2)×Y1=VN2×Y2, and thus (VN2/VN1)=Y1/(Y1+Y2). By arranging this, (VN2/VN1) is expressed as follows:

$$( V N 2 / V N 1 ) = ( j ω C 1 \times R 1 i ) / ( 1 + j ω Ci \times R 1 i ) \qquad ( 7 )$$

$$Here , Ci = ( C 1 + C 2 i + Cai ) . \qquad ( 8 )$$

Therefore, according to Expression (7), |VN2/VN1| is expressed as follows:

$$\vert V N 2 / V N 1 \vert = ( ω C 1 \times R 1 i ) / {\{ 1 + {( ω Ci \times R 1 i )}^{2} \}}^{( 1 / 2 )} \qquad ( 9 )$$

(|VN3/VN2|) in Expression (6) is solved. For node N3 in FIG. 2, solving the nodal equation of Kirchhoff's law with admittance Y3 as Y3=(1+jω(Cao+C2o)×Ro)/Ro and resistor Ro as Ro=(Rao×R1o)/(Rao+R1o) . . . (10) gives (gm1×VN2)=−VN3×Y3, and thus (VN3/VN2)=−(gm1/Y3). By arranging this, (VN3/VN2) is expressed as follows:

$$( V N 3 / V N 2 ) = - ( gm 1 \times Ro ) / ( 1 + j ω Co \times Ro ) \qquad ( 11 )$$

$$Here , capacitor Co is Co = ( Cao + C 2 o ) . \qquad ( 12 )$$

According to Expression (11), |VN3/VN2| is expressed as follows:

$$\vert V N 3 / V N 2 \vert = - ( gm 1 \times Ro ) / {\{ 1 + {( ω Co \times Ro )}^{2} \}}^{( 1 / 2 )} \qquad ( 13 )$$

By substituting Expressions (9) and (13) into Expression (6), voltage amplification factor |Gx1| of amplifier circuit A101 is expressed as follows:

$$\vert Gx 1 \vert = - ( gm 1 \times Ro ) \times \{ ( ω C 1 \times R 1 i ) / {( 1 + {( ω Ci \times R 1 i )}^{2} )}^{( 1 / 2 )} \} \times \{ 1 / {( 1 + {( ω Co \times Ro )}^{2} )}^{( 1 / 2 )} \} \qquad ( 14 )$$

Here, the frequency response of voltage amplification factor |Gx1| of amplifier circuit A101 is shown.

In Expression (14), the second term {(ωC1×R1i)/(1+(ωCi×R1i)²)^{(1/2)}} is the transfer function of a high-pass filter, and cut-off frequency fc1 is expressed as follows:

$$fc 1 = 1 / \{ 2 π Ci \times R 1 i \} \qquad ( 15 )$$

In contrast, in Expression (14), the third term {1/(1+(ωCo×Ro)²)^{(1/2)}} is the transfer function of a low-pass filter, and cut-off frequency fc2 is expressed as follows:

$$fc 2 = 1 / \{ 2 π Co \times Ro \} \qquad ( 16 )$$

Expressions (15) and (16) show that amplifier circuit A101 constitutes a bandpass filter having frequency band f1 that satisfies fc1<<f1<<fc2. The specific range is as follows:

$$1 / \{ 2 π Ci \times R 1 i \} << f 1 << 1 / \{ 2 π Co \times Ro \} \qquad ( 17 )$$

Substituting Expressions (1) through (4) and Expressions (8), (10), and (12) into Expression (17) provides the following:

$$fc 1 = 1 / \{ 2 π ( C 1 + \vert Av \vert \times C 2 + Cai ) \times ( R 1 / \vert Av \vert ) \} \qquad ( 18 )$$

$$fc 2 = 1 / \{ 2 π ( Cao + C 2 ) \times ( ( Rao \times R 1 ) / ( Rao + R 1 ) ) \} \qquad ( 19 )$$

Here, since it can be assumed that capacitors C1 and C2 are sufficiently greater in capacitance than input capacitor Cai of inverter INV1, capacitor C2 is sufficiently greater in capacitance than output capacitor Cao of inverter INV1, and feedback resistor R1 is sufficiently greater in resistance than output resistor Rao of inverter INV1, Expressions (18) and (19) become as follows:

$$fc 1 = 1 / \{ 2 π ( C 1 / \vert Av \vert + C 2 ) \times R 1 \} \qquad ( 20 )$$

$$fc 2 = 1 / \{ 2 π C 2 \times Rao \} \qquad ( 21 )$$

Therefore, frequency band f1 is as follows:

$$1 / \{ 2 π ( C 1 / \vert Av \vert + C 2 ) \times R 1 \} << f 1 << 1 / \{ 2 π C 2 \times Rao \} \qquad ( 22 )$$

Here, for example, when C1=10×C2 and |Av|=10, frequency band f1 is as follows:

$$1 / \{ 4 π C 2 \times R 1 \} << f 1 << 1 / \{ 2 π C 2 \times Rao \} \qquad ( 23 )$$

When voltage amplification factor |Av| is sufficiently high due to inverter INV1 or another element of amplifier circuit A101, frequency band f1 is 1/{2nC2×R1}<<f1<<1/{2nC2×Rao}.

In Expression (22) or (23), feedback resistor R1 may be high in resistance because feedback resistor R1 sets the DC bias of inverter INV1. The resistance value of feedback resistor R1 is at least 1 MΩ, for example. In contrast, resistor Rao is the output resistor of inverter INV1 and may be low in resistance. The resistance value of resistor Rao is at most 100Ω, for example. Accordingly, although amplifier circuit A101 constitutes a bandpass filter, frequency band f1 of amplifier circuit A101 can be widely set by adjusting capacitors C1 and C2 and feedback resistor R1. Here, that the frequency band can be widely set means that the frequency band of inverter INV1 is a frequency band wide enough to include a frequency band including the resonance frequency of the parasitic oscillation in addition to the resonance frequency of the main oscillation of the oscillator, or a frequency band wider than that, and the same holds true hereinafter. For example, when the resonance frequency of the main oscillation is 10 MHz and the resonance frequency of the parasitic oscillation is 30 MHz, the resistance values of feedback resistor R1 and output resistor Rao differ by four or more digits in Expression (23) above, and thus a wide frequency band can be set. Note that although inverter INV1 is used as the inverting amplification function, it is possible to use a differential amplifier circuit that: includes an inverting input terminal and an output terminal to which the input node and the output node of inverter INV1 are connected; and receives, at a non-inverting input terminal, (VDD/2) as a reference voltage, or receives another reference voltage. It is also possible to use a different amplifier circuit.

Next, voltage amplification factor |Gx1| of amplifier circuit A101 in frequency band f1 of Expression (22) or (23) is obtained. Voltage amplification factor |Gx1| of amplifier circuit A101 is expressed as below by substituting Expressions (1), (3), and (8) into Expression (14).

$$\vert Gx 1 \vert = - ( gm 1 \times Ro ) \times \{ ( C 1 / \vert Av \vert ) / ( C 2 + ( C 1 + Cai ) / \vert Av \vert ) \} \qquad ( 24 )$$

Here, when voltage amplification factor |Av| of inverter INV1 is |Av| =gm1×Ro and capacitors C1 and C2 are sufficiently greater in capacitance than input capacitor Cai of inverter INV1, Expression (24) becomes as follows:

$$\vert Gx 1 \vert = - ( C 1 / ( C 1 / \vert Av \vert + C 2 ) ) \qquad ( 25 )$$

Here, for example, when C1=10×C2 and |Av|=10, voltage amplification factor |Gx1| is |Gx1|=−5 according to Expression (25). Also, when voltage amplification factor |Av| of the amplifier device of amplifier circuit A101 is |Av|=100, then, according to Expression (25),

$$\vert Gx 1 \vert = - ( C 1 / C 2 ) . \qquad ( 26 )$$

Accordingly, it is possible to set voltage amplification factor |Gx1| according to the ratio between capacitors C1 and C2.

According to the above, Expressions (22) and (23), which express frequency band f1, and Expressions (25) and (26), which express voltage amplification factor |Gx1|, were obtained for amplifier circuit A101. Hereinafter, using Expressions (22), (23), (25), and (26), frequency bands f2 and f3 and voltage amplification factors |Gx2| and |Gx3| of amplifier circuits A102 and A103 are obtained to obtain frequency band fg and voltage amplification factor |Gx| of amplifier A1.

First, regarding amplifier circuit A102, amplifier circuit A102 is the same as amplifier circuit A101 in circuit configuration and also in configuration of the external load connected to node N3, and therefore, f2=f1 is established for frequency band f2, and |Gx2|=|Gx1| is established for voltage amplification factor |Gx2|.

Next, regarding amplifier circuit A103, amplifier circuit A103 is the same as amplifier circuit A101 in circuit configuration, but load capacitor CL2 is connected to node N3 in parallel with capacitor C2. Therefore, according to Expression (22), frequency band f3 is expressed as follows:

$$1 / \{ 2 π ( C 1 / \vert Av \vert + C 2 ) \times R 1 \} << f 3 << 1 / \{ 2 π ( C 2 + CL 2 ) \times Rao \} \qquad ( 27 )$$

Here, for example, when C1=10×C2, |Av|=10, and load capacitor CL2 is sufficiently greater than capacitor C2 in capacitance, frequency band f3 is as follows:

$$1 / \{ 4 π C 2 \times R 1 \} << f 3 << 1 / \{ 2 π CL 2 \times Rao \} \qquad ( 28 )$$

Here, in frequency band f3 of amplifier circuit A103, too, feedback resistor R1 may be high in resistance because feedback resistor R1 sets the DC bias of inverter INV1. The resistance value of feedback resistor R1 is at least 1 MΩ, for example. In contrast, resistor Rao is the output resistor of inverter INV1 and may be low in resistance. The resistance value of resistor Rao is at most 100Ω, for example. When load capacitor CL2 is assumed to be at least 10 times and at most 100 times as high as capacitor C2 in capacitance, frequency band f3 can be set to a frequency band of two or more digits, thus making it possible to use a crystal oscillator that is different in resonance frequency of the main oscillation. It is clear that although frequency band f3 of amplifier circuit A103 is the same as frequency bands f1 and f2 of amplifier circuits A101 and A102 in lower cutoff frequency, frequency band f3 of amplifier circuit A103 is low in upper cutoff frequency as compared to frequency bands f1 and f2 of amplifier circuits A101 and A102 due to load capacitor CL2. Accordingly, the upper cutoff frequency of frequency band f3 of amplifier circuit A103 is the upper cutoff frequency of amplifier A1.

On the other hand, since amplifier circuit A103 is the same as amplifier circuits A101 and A102 in configuration, voltage amplification factor |Gx3| of amplifier circuit A103 is equivalent to the voltage amplification factors of amplifier circuits A101 and A102 in frequency band f3 expressed by Expressions (27) and (28). Therefore, this can be expressed as follows:

$$\vert Gx 3 \vert = \vert Gx 1 \vert = \vert Gx 2 \vert \qquad ( 29 )$$

This shows that when amplifier circuits having the same configuration are used as amplifier circuits A101, A102, and A103, the voltage amplification factors of all the amplifier circuits become the same in the frequency band expressed by Expression (27) or (28), regardless of, for example, a parasitic capacitor or load capacitor connected to output terminal OUT of amplifier A1.

Accordingly, frequency band fg of amplifier A1 is shown below according to Expression (27) that expresses the frequency band in which all of amplifier circuits A101, A102, and A103 can amplify voltage.

$$1 / \{ 2 π ( C 1 / \vert Av \vert + C 2 ) \times R 1 \} << fg << 1 / \{ 2 π CL 2 \times Rao \} \qquad ( 30 )$$

For example, when C1=10×C2 and |Av|=10, frequency band fg is as follows:

$$1 / \{ 4 π C 2 \times R 1 \} << fg << 1 / \{ 2 π CL 2 \times Rao \} \qquad ( 31 )$$

When voltage amplification factor |Av| of inverter INV1 is sufficiently high, Expression (30) becomes as follows:

$$\\ \begin{matrix}1 / \{ 2 π C 2 \times R 1 \} << fg << 1 / \{ 2 π CL 2 \times Rao \} & ( 32 )\end{matrix}$$

By substituting Expression (25) into Expression (5), voltage amplification factor |Gx| of amplifier A1 is expressed as follows:

$$\\ \begin{matrix}\vert Gx \vert = {\vert Gx 1 \vert}^{3} = - {\{ C 1 / ( C 1 / \vert Av \vert + C 2 ) \}}^{3} & ( 33 )\end{matrix}$$

When C1=10×C2 and |Av|=10, then |Gx|=−125. When voltage amplification factor |Av| of inverter INV1 is sufficiently high, |Gx| is expressed as follows:

$$\\ \begin{matrix}\vert Gx \vert = - {\{ C 1 / C 2 \}}^{3} & ( 34 )\end{matrix}$$

Accordingly, voltage amplification factor |Gx| of amplifier A1 can be set according to capacitors C1 and C2.

As described above, since amplifier circuits A101, A102, and A103 each include gain setter G1 that includes (i) capacitor C1 on the input side of inverter INV1 that performs inverting amplification and (ii) capacitor C2 identical to capacitor C1 in type and connected between the input node and the output node of inverter INV1, it is possible to arbitrarily set the voltage amplification factor of the amplifier circuit. This makes it possible to avoid the voltage amplification factor of amplifier A1 from being excessive, thus achieving a shorter startup time of the oscillator circuit and avoidance of abnormal oscillation attributable to parasitic oscillation of the oscillator caused by an excessive voltage amplification factor. Furthermore, since a wide frequency band can be set according to gain setter G1 and feedback resistor R1, it is possible to apply the same oscillator circuit 100 to oscillator 101 different in main oscillation, thus making oscillator circuit 100 versatile. The oscillator circuit for the oscillator consumes the most current during the startup time; however, by shortening the startup time, it is possible to reduce unnecessary current consumption by the oscillator circuit. In addition, it is also possible to reduce the current consumption of, for example, IoT devices and mobile devices that transition from the standby state to the recovery state many times.

Note that it is sufficient so long as amplifier A1 constituted by amplifier circuits in a plurality of stages includes at least one amplifier circuit having the present configuration, and the other amplifier circuits may be ordinary inverter circuits, buffer circuits, or differential amplifiers etc. Amplifier A1 may be configured by combining an amplifier circuit having the present configuration and a non-inverting amplifier circuit.

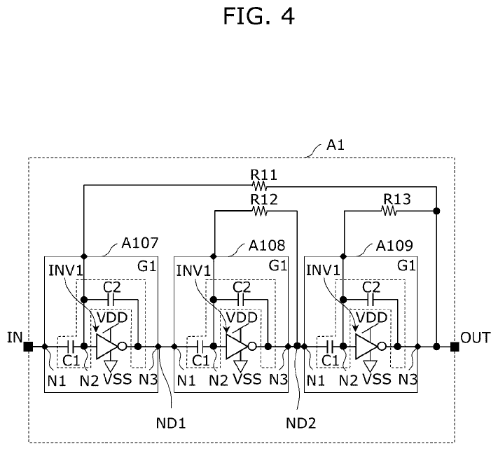

The connection of feedback resistor R1 illustrated in FIG. 1 is not limited to the present configuration so long as the frequency band of amplifier A1 can be secured and the DC bias of inverter INV1 can be set. As another connection example of feedback resistor R1, each of feedback resistors R11, R12, and R13 of the respective amplifier circuits may be provided between the input node of inverter INV1 of the corresponding amplifier circuit and a node of another amplifier circuit as illustrated in FIG. 4.

### Variation

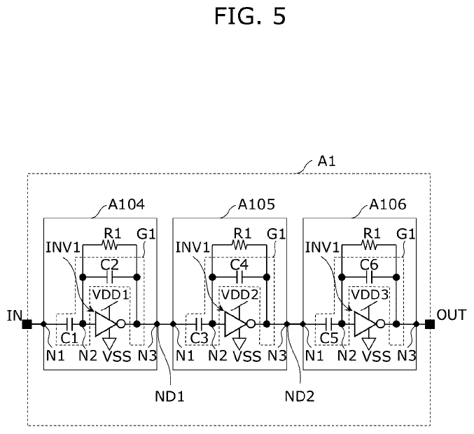

FIG. 5 illustrates a variation of amplifier A1 in FIG. 1, and illustrates a configuration in which capacitors C1 and C2 in amplifier circuits A101, A102, and A103 are replaced with capacitors C1 and C2 in amplifier circuit A104, capacitors C3 and C4 in amplifier circuit A105, and capacitors C5 and C6 in amplifier circuit A106, and furthermore, power supply voltage VDD of inverter INV1 in each of amplifier circuits A101, A102, and A103 is replaced with VDD1 in amplifier circuit A104, VDD2 in amplifier circuit A105, and VDD3 in amplifier circuit A106.

The above replacements enable setting of voltage amplification factors |Gx1|, |Gx2|, and |Gx3| for amplifier circuits A104, A105, and A106. Here, by substituting Expression (8) into Expression (9), input voltage VN2 of inverter INV1 of amplifier circuit A106 in frequency band fg based on Expression (30) is expressed as follows:

$$\\ \begin{matrix}\vert VN 2 \vert = ( \vert VN 1 \vert \times C 5 ) / ( C 5 / \vert Av \vert + C 6 ) & ( 35 )\end{matrix}$$

With Expression (35), the input voltage level of inverter INV1 can be set according to capacitors C5 and C6 and voltage amplification factor |Av| of inverter INV1. Therefore, it is also possible to set the output current of inverter INV1, and the output current can be set to the excitation level of the oscillator. Furthermore, power supply voltage VDD3 of inverter INV1 can be set as one factor determining the output current of amplifier circuit A106.

Accordingly, it is also possible to meet the specifications of the excitation level of the oscillator by optimally setting the capacitance of the capacitor provided on the input side of inverter INV1 included in each of amplifier circuits A104, A105, and A106 that are included in amplifier A1 and the capacitance of the capacitor provided between the input and the output of inverter INV1.

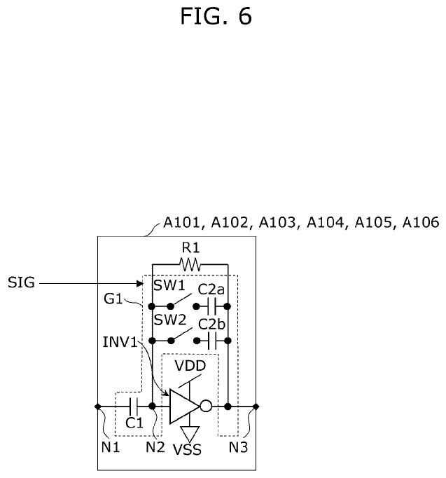

Note that as illustrated in FIG. 6, in each of amplifier circuits A101 through A106, capacitors provided between the input and the output of inverter INV1 may be disposed in parallel, and capacitors C2a and C2b may be switched by switches SW1 and SW2 according to control signal SIG. For example, control signal SIG is used to control switches SW1 and SW2 between the time of startup and the steady oscillation state of the oscillator circuit; capacitor C2a is placed in a usable state at the time of startup and capacitor C2b is placed in a usable state in the steady oscillation state. This makes it possible to both set an optimal voltage amplification factor of amplifier A1 at the time of startup and meet the specifications of the excitation level of the oscillator in the steady oscillation state. The specifications of the oscillator can be met without use of a damping resistor. Note that although not illustrated in the drawings, the capacitor provided on the input side of inverter INV1 may be switched by a switch. As described above, the voltage amplification factor of amplifier A1 may be switched by setting one or both of the impedance of the first element and the impedance of the second element according to a control signal.

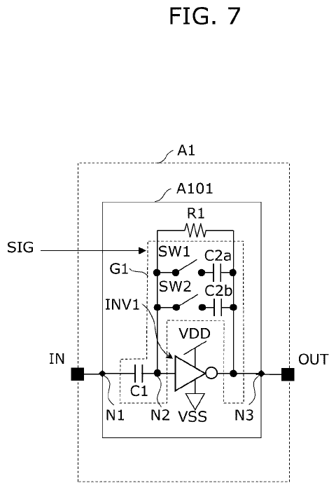

As illustrated in FIG. 7, focusing on meeting the specifications of the excitation level of the oscillator, the amplifier circuit in a single stage illustrated in FIG. 6 can be applied to amplifier A1 in FIG. 1. By switching capacitors C2a and C2b using switches SW1 and SW2 according to control signal SIG, it is possible to make a setting that meets the specifications of the excitation level of the oscillator without use of a damping resistor. Note that although not illustrated in the drawings, the capacitor provided on the input side of inverter INV1 may be switched by a switch.

### Variation

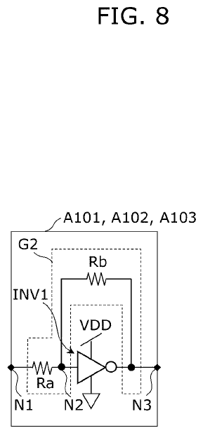

FIG. 8 illustrates a variation of amplifier circuits A101, A102, and A103 in FIG. 1, and illustrates a configuration in which capacitors C1 and C2 constituting gain setter G1 in each of amplifier circuits A101, A102, and A103 are replaced with resistors Ra and Rb, respectively, and feedback resistor R1 is removed. Resistor Ra is an example of the first element and the first resistor, and resistor Rb is an example of the second element and the second resistor. Here, resistors Ra and Rb constitute gain setter G2, and set voltage amplification factors |Gx1|, |Gx2|, and |Gx3| of amplifier circuits A101, A102, and A103 in the same manner as described above. Resistor Rb also sets the DC level of the input voltage of inverter INV1 of the amplifier circuit.

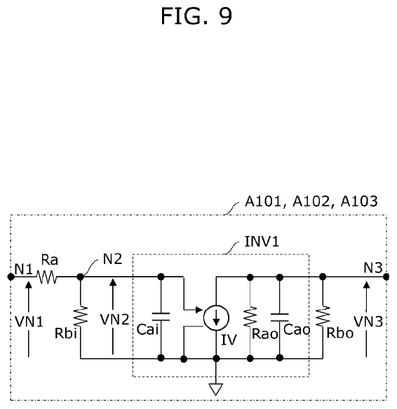

FIG. 9 is an equivalent circuit of amplifier circuits A101, A102, and A103 in FIG. 8. In the same manner as the changes from FIG. 1 to FIG. 8, the equivalent circuit in FIG. 2 is changed to the equivalent circuit in FIG. 9 such that capacitor C1 is replaced with resistor Ra, resistor R1i is replaced with resistor Rbi, resistor R1o is replaced with resistor Rbo, and capacitor C2i is removed.

Voltage amplification factor |Gx1| of amplifier circuit A101 may be obtained as described above so as to obtain voltage amplification factor |Gx| of amplifier A1. (VN2/VN1) and (VN3/VN2) of amplifier circuit A101 can be obtained based on Expressions (7) and (11). First, (VN2/VN1) is obtained. By substituting jωC1=(1/Ra), R1i=Rbi, R1o=Rbo, jωC2i=0, and Expression (8) into Expression (7), Expression (7) can be transformed as follows:

$$\\ \begin{matrix}( VN 2 / VN 1 ) = ( Rm / Ra ) \times \{ 1 / ( 1 + j ω Cai \times Rm ) \} & ( 36 )\end{matrix}$$

Accordingly, |VN2/VN1| is expressed as follows:

$$\\ \begin{matrix}\vert VN 2 / VN 1 \vert = ( Rm / Ra ) / {( 1 + {( ω Cai \times Rm )}^{2} )}^{( 1 / 2 )} & ( 37 )\end{matrix}$$

Here, Rm=(Ra×Rbi)/(Ra+Rbi). When voltage amplification factor |Av| of inverter INV1 is sufficiently greater than 1, resistor Rbi=Rb/|Av| according to Expression (3), and thus Rm is expressed as follows:

$$\\ \begin{matrix}Rm = ( 1 / \vert Av \vert ) \times ( Ra \times Rb ) / ( Ra + Rb / \vert Av \vert ) & ( 38 )\end{matrix}$$

Next, (VN3/VN2) is obtained. Substituting R1o=Rbo, jωC2o=0, and Expressions (10) and (12) into Expression (11) provides the following:

$$\\ \begin{matrix}( VN 3 / VN 2 ) = - ( gm 1 \times Rn ) / ( 1 + j ω Cao \times Rn ) & ( 39 )\end{matrix}$$

Accordingly, |VN3/VN2| is expressed as follows:

$$\\ \begin{matrix}\vert VN 3 / VN 2 \vert = - ( gm 1 \times Rn ) / {( 1 + {( ω Cao \times Rn )}^{2} )}^{( 1 / 2 )} & ( 40 )\end{matrix}$$

Here, Rn=(Rao×Rbo)/(Rao+Rbo), and Rbo=Rb according to Expression (4), and therefore, Rn is expressed as follows:

$$\\ \begin{matrix}Rn = ( Rao \times Rb ) / ( Rao + Rb ) & ( 41 )\end{matrix}$$

Expressions (37) and (40) each express a configuration of the low-pass filter. Therefore, frequency band f4 of amplifier circuit A101 is:

$$\\ \begin{matrix}f 4 << 1 / ( 2 π \times Cai \times Rm ) or & Expression ( 42 )\end{matrix}$$

$$\\ \begin{matrix}f 4 << 1 / ( 2 π \times Cao \times Rn ) & Expression ( 43 )\end{matrix}$$

Furthermore, according to Expressions (37) and (40), voltage amplification factor |Gx1| of amplifier circuit A101 in frequency band f4 is expressed as follows:

$$\\ \begin{matrix}\vert Gx 1 \vert = - ( gm 1 \times Rn ) \times ( Rm / Ra ) & ( 44 )\end{matrix}$$

Here, |Av|=gm1×Rn, and substituting Expression (38) into Expression (44) provides the following:

$$\\ \begin{matrix}\vert Gx 1 \vert = - Rb / ( Ra + Rb / \vert Av \vert ) & ( 45 )\end{matrix}$$

Accordingly, voltage amplification factor |Gx1| can be set according to resistors Ra and Rb.

According to the above, voltage amplification factor |Gx| and frequency band fg of amplifier A1 are obtained. By substituting Expression (45) that expresses voltage amplification factor |Gx1| of amplifier circuit A101 into Expression (5), voltage amplification factor |Gx| of amplifier A1 is expressed as follows:

$$\\ \begin{matrix}\vert Gx \vert = ( {\vert Gx 1 \vert}^{3} ) = - {\{ Rb / ( Ra + Rb / \vert Av \vert ) \}}^{3} & ( 46 )\end{matrix}$$

Replacement of capacitor Cao in Expression (43) which expresses frequency band f4 with load capacitor CL2 connected to the output terminal of amplifier A1 that is connected in parallel with capacitor Cao and is sufficiently greater in capacitance than capacitor Cao provides the following:

$$\\ \begin{matrix}fg << 1 / ( 2 π \times CL 2 \times Rao ) & ( 47 )\end{matrix}$$

Therefore, voltage amplification factor |Gx| of amplifier A1 can be set based on resistors Ra and Rb included in gain setter G2 of each of amplifier circuits A101, A102, and A103. For example, when Rb=10×Ra and |Av|=10, then |Gx|=−125. When voltage amplification factor |Av| of inverter INV1 is sufficiently high, |Gx|=−{Rb/Ra}³. Since voltage amplification factor |Gx| can be set according to the ratio between Rb and Ra, the DC bias of inverter INV1 can be set according to Rb. Furthermore, frequency band fg is set according to load capacitor CL2 and output resistor Rao of inverter INV1, and thus a wide frequency band can be set. Note that although not illustrated in the drawings, one or both of resistor Ra provided on the input side of inverter INV1 and resistor Rb provided between the input and the output of inverter INV1 may have a series-parallel configuration, and the resistance value may be switched using a switch according to control signal SIG.

As described above, since each of amplifier circuits A101, A102, and A103 includes gain setter G2 that includes (i) resistor Ra connected to the input node of inverter INV1 that performs inverting amplification and (ii) resistor Rb connected between the input node and the output node of inverter INV1, it is possible to arbitrarily set the voltage amplification factor of the amplifier circuit. This makes it possible to avoid the voltage amplification factor of amplifier A1 from being excessive, thus achieving a shorter startup time of oscillator circuit 100 and avoidance of abnormal oscillation attributable to parasitic oscillation of the oscillator caused by an excessive voltage amplification factor. Furthermore, the frequency band can be widely set, and the same oscillator circuit 100 can be applied to oscillator 101 different in resonance frequency of the main oscillation, thus enabling versatile use of oscillator circuit 100. Oscillator circuit 100 for oscillator 101 consumes the most current during the startup time; however, by shortening the startup time, it is possible to reduce unnecessary current consumption by oscillator circuit 100. In addition, it is also possible to reduce the current consumption of, for example, IoT devices and mobile devices that transition from the standby state to the recovery state many times.

That is to say, by including the gain setter that includes elements of the same type at the input node and between the input node and the output node of the inverting amplifier device included in the amplifier circuit, the voltage amplification factor of amplifier A1 can be arbitrarily set, and the same oscillator circuit 100 can be applied to oscillator 101 different in resonance frequency of the main oscillation. This enables versatile use of oscillator circuit 100.

The elements of the same type need not be limited to capacitors or resistors, so long as the elements of the same type have the function to set the voltage amplification factor.

Thus far, the description has been given of the amplifier devices that are, for example, inverters in a plurality of stages for obtaining a high voltage amplification factor; however, an amplifier device in a single stage may be used so long as a sufficient voltage amplification factor can be obtained with the amplifier device in a single stage, and the voltage amplification factor may be set by providing identical devices at the input of the amplifier device and between the input and the output of the amplifier device. Furthermore, so long as the amplifier circuit having the present configuration is included in at least one stage, amplifier circuits may be provided in three or more stages.

Since it is sufficient so long as the amplifier is capable of performing inverting amplification, the amplifier device included in the amplifier may be a combination of an amplifier device having the inverting amplification function and a positive logic amplifier device.

Although only an exemplary embodiment of the present disclosure has been described in detail above, those skilled in the art will readily appreciate that many modifications are possible in the exemplary embodiment without materially departing from the novel teachings and advantages of the present disclosure. Accordingly, all such modifications are intended to be included within the scope of the present disclosure.

### INDUSTRIAL APPLICABILITY

The oscillator circuit according to the present disclosure achieves a shorter startup time while inhibiting abnormal oscillation during the period from the startup to the steady oscillation state and performing stable oscillation operation, and is useful for, for example, IoT-related devices such as cellular phones and other mobile devices that require a shorter recovery time from a stopped state or a standby state to chip startup.

1. An oscillator circuit comprising:
an oscillator; and
an amplifier that amplifies a voltage of the oscillator, wherein
the amplifier includes an amplifier circuit that includes:
an amplifier device that inverts and amplifies an input voltage and outputs a resulting voltage;
a first element connected to an input node of the amplifier device; and
a second element identical to the first element in type and connected between the input node and an output node of the amplifier device.

2. The oscillator circuit according to claim 1, wherein
a voltage amplification factor of the amplifier is set based on an impedance of the first element and an impedance of the second element.

3. The oscillator circuit according to claim 1, wherein
a voltage amplification factor of the amplifier is switched by setting one or both of an impedance of the first element and an impedance of the second element according to a control signal.

4. The oscillator circuit according to claim 1, wherein
the amplifier device is an inverter.

5. The oscillator circuit according to claim 1, wherein
the amplifier device is a differential amplifier circuit.

6. The oscillator circuit according to claim 1, wherein
the first element is a first capacitor, and
the second element is a second capacitor.

7. The oscillator circuit according to claim 1, wherein
the first element is a first resistor, and
the second element is a second resistor.

8. An oscillator circuit comprising:
an oscillator; and
an amplifier that amplifies a voltage of the oscillator, wherein
the amplifier includes amplifier circuits in a plurality of stages, and one or more of the amplifier circuits each include:
an amplifier device that inverts and amplifies an input voltage and outputs a resulting voltage;
a first element connected to an input node of the amplifier device; and
a second element identical to the first element in type and connected between the input node and an output node of the amplifier device.

9. The oscillator circuit according to claim 8, wherein
a voltage amplification factor of the amplifier is set based on an impedance of the first element and an impedance of the second element.

10. The oscillator circuit according to claim 8, wherein
a voltage amplification factor of the amplifier is switched by setting one or both of an impedance of the first element and an impedance of the second element according to a control signal.

11. The oscillator circuit according to claim 8, wherein
the amplifier device is an inverter.

12. The oscillator circuit according to claim 8, wherein
the amplifier device is a differential amplifier circuit.

13. The oscillator circuit according to claim 8, wherein
the first element is a first capacitor, and
the second element is a second capacitor.

14. The oscillator circuit according to claim 8, wherein
the first element is a first resistor, and
the second element is a second resistor.
